(19) United States
(12) Patent Application Publication
(10) Pub. No.: US 2002/0021551 A1
(43) Pub. Date: Feb. 21, 2002

(54) Electronic apparatus having connectors for connection with peripheral equipments and connector device used for electronic apparatus

(75) Inventor: Kazuhiko Kashiwagi, Tokorozawa-shi (JP)

Correspondence Address: Finnegan, Henderson, Farabow,, Garrett & Dunner, L.L.P., 1300 I Street, N.W., Washington, DC, 20005-3315, US

(73) Assignee: KABUSHIKI KAISHA TOSHIBA

(21) Appl. No.: 09/916,296

(22) Filed: Jul. 30, 2001

(30) Foreign Application Priority Data
Jul. 31, 2000 (JP) 2000-231860

(51) Int. Cl. G06F 1/16; H05K 5/00; H05K 7/00

(52) U.S. Cl. 361/683

(57) ABSTRACT

A desktop computer as an electronic apparatus comprises a main body having a vertically extending rear wall and a PRT connector supported by the main body. A cable connector attached to a printer cable is detachably connected to a connection section of the PRT connector. The PRT connector is movable between a first position directing the connection section sideways against the external wall and a second position directing the connection section downward against the external wall.

### CROSS-REFERENCE TO RELATED APPLICATIONS

This application is based upon and claims the benefit of priority from the prior Japanese Patent Application No. 2000-231860, filed Jul. 31, 2000, the entire contents of which are incorporated herein by reference.

### BACKGROUND OF THE INVENTION

1. Field of the Invention

The present invention relates to an electronic apparatus such as a desktop computer integrated with a liquid crystal display module and a main body and to a connector device used for the electronic apparatus. More specifically, the present invention concerns a structure for connecting peripheral equipments such as a printer and a keyboard to the main body.

2. Description of the Related Art

In recent years, there are provided various so-called all-in-one desktop LCD computers integrated with all functions. This type of desktop computer saves a footprint to a half or smaller than a conventional tower computer using a CRT display. This is a space-saving advantage when the desktop computer is placed on a tabletop.

A conventional all-in-one desktop LCD computer has a main body which is placed on an installation surface such as a tabletop. The main body comprises a box-shaped housing and a foot for supporting this housing. The housing contains major constituent elements such as a CPU-mounted printed circuit board, a hard disk drive device, and a liquid crystal display module.

The rear of the housing is provided with a plurality of connectors. These connectors are used for connecting various peripheral equipments such as a printer, a keyboard, a mouse, and USB devices. Each connector has an exposed connection section on the housing rear. The above-mentioned peripheral equipment has a cable. A cable connector at the cable end is detachably connected to a specified connector connection section.

On the all-in-one desktop LCD computer, the connector connection section on the housing rear is oriented toward the rear of the housing. This enables easy visual inspection for connection section positions and shapes and improves workability when connecting a cable connector to the connection section.

When the cable connector is connected to the connector connection section, the cable connector protrudes toward the rear of the housing. This requires a space for mounting cable connectors or cable ends on the housing rear. When there is a vertical wall at the rear of the main body, it is impossible to place the main body closely to the vertical wall. This may sacrifice the space-saving benefit.

Jpn. Pat. Appln. KOKAI Publication No. 2000-357027 (U.S. patent application No. 09/539,417: filing date Mar. 30, 2000) discloses an all-in-one desktop LCD computer which arranges a plurality of connectors with their connection sections oriented downward at the bottom of a housing. When a cable connector is connected to the connector's connection section on this computer, the cable connector protrudes downward from the housing. The cable connector does not protrude rearward from the housing, eliminating the need for securing a space for cable connectors at the rear of the main body.

When the connector connection section faces downward, it is difficult to visually check the connection section position or shape. When connecting a cable connector to the connector connection section, a user may have to look into the connector connection section from the bottom and grope for the connection section and the cable connector for positioning, decreasing workability for connecting cable connectors.

If the connector's connection section is hardly visible from the outside, the cable connector is incompletely positioned to the connector. The user may forcibly insert the cable connector to the connection section. This may damage the connector connection section or a cable connector's pin terminal.

### BRIEF SUMMARY OF THE INVENTION

The present invention has been made in consideration of the foregoing. It is therefore an object of the present invention to provide an electronic apparatus and a connector device capable of easily connecting a cable connector to the connector connection section without sacrificing the space-saving benefit.

In order to achieve the above-mentioned objects, an electronic apparatus according to the first aspect of the present invention comprises a main body having an external wall; and at least one connector supported by the main body. The connector has a connection section to which a cable connector attached to a cable is detachably connected. The connector is movable between a first position directing the connection section sideways against the external wall and a second position directing the connection section downward against the external wall.

In order to achieve the above-mentioned objects, an electronic apparatus according to the second aspect of the present invention comprises a main body having an external wall; and a connector unit supported by the main body. The connector unit comprises a connector housing, a connector board contained in the connector housing, and at least one connector mounted on the connector board and having a connection section detachably connecting a cable connector attached to a cable. The connector unit is movable between a first position directing the connection section sideways against the external wall and a second position directing the connection section downward against the external wall.

In order to achieve the above-mentioned objects, a connector device according to the third aspect of the present invention comprises a connector housing supported by an electronic apparatus having an external wall; and at least one connector enclosed in the connector housing and having a connection section detachably connecting a cable connector attached to a cable. The connector housing is movable between a first position directing the connection section sideways against the external wall and a second position directing the connection section downward against the external wall.

In order to achieve the above-mentioned objects, an electronic apparatus according to the fourth aspect of the present invention comprises a main body having an external wall; and a connector unit supported by the main body. This connector unit includes a plurality of connector modules having connection sections detachably connecting cable connectors attached to cables and a base selectively and detachably supporting the connector modules. The connector unit is movable between a first position directing the connection section sideways against the external wall and a second position directing the connection section downward against the external wall.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate presently embodiments of the invention, and together with the general description given above and the detailed description of the embodiments given below, serve to explain the principles of the invention.

FIG. 1 is a side view of a computer system including a desktop computer and a printer connected to the computer according to a first embodiment of the present invention;

FIG. 2 is a partial cross sectional side view of a desktop computer with a connector unit rotated to a first position;

FIG. 3 is a partial cross sectional side view of a desktop computer with a connector unit rotated to a second position;

FIG. 4 is a rear view showing the connector unit rotated to the first position viewed from the rear of a main body;

FIG. 5 is a perspective view showing positional relation among the connector unit and a plurality of cable connectors;

FIG. 6 is a perspective view showing a plurality of connectors mounted on a connector board;

FIG. 7 is a sectional view showing a projection of a connector housing engaged with a first latch recess of a connector support;

FIG. 8 is a sectional view showing the connector support where a connector unit is inserted;

FIG. 9 is a partial cross sectional side view of a desktop computer according to a second embodiment of the present invention with a connector unit removed from a main body;

FIG. 10 is a perspective view of the connector unit;

FIG. 11 is a rear view of a connector support where the connector unit is inserted;

FIG. 12A is a sectional view showing positional relation among a bearing hole and a first latch recess of the connector support, and a shaft portion and a projection of the connector housing;

FIG. 12B is a sectional view showing that the shaft portion is fit into the bearing hole;

FIG. 13 is a sectional view of the connector support where the connector unit is inserted;

FIG. 14 is a plan view of a plurality of connector modules screwed on a base according to a third embodiment of the present invention; and

FIG. 15 is a perspective view showing positional relation among a plurality of connector modules and the base.

### DETAILED DESCRIPTION OF THE INVENTION

The following describes the first embodiment of the present invention applied to a desktop computer with reference to FIGS. 1 to 8.

The computer system in FIG. 1 includes electronic apparatuses such as a desktop computer 1 and a printer 2 connected to the desktop computer 1. The desktop computer 1 comprises a main body 3 and a keyboard 4 connected to the main body 3. The main body 3 and the keyboard 4 are placed on a level installation surface 5 such as a tabletop.

The printer 2 has a printer cable 2a. The printer cable 2a is provided with a cable connector 6 at its end. The cable connector 6 has a plurality of pin terminals (not shown).

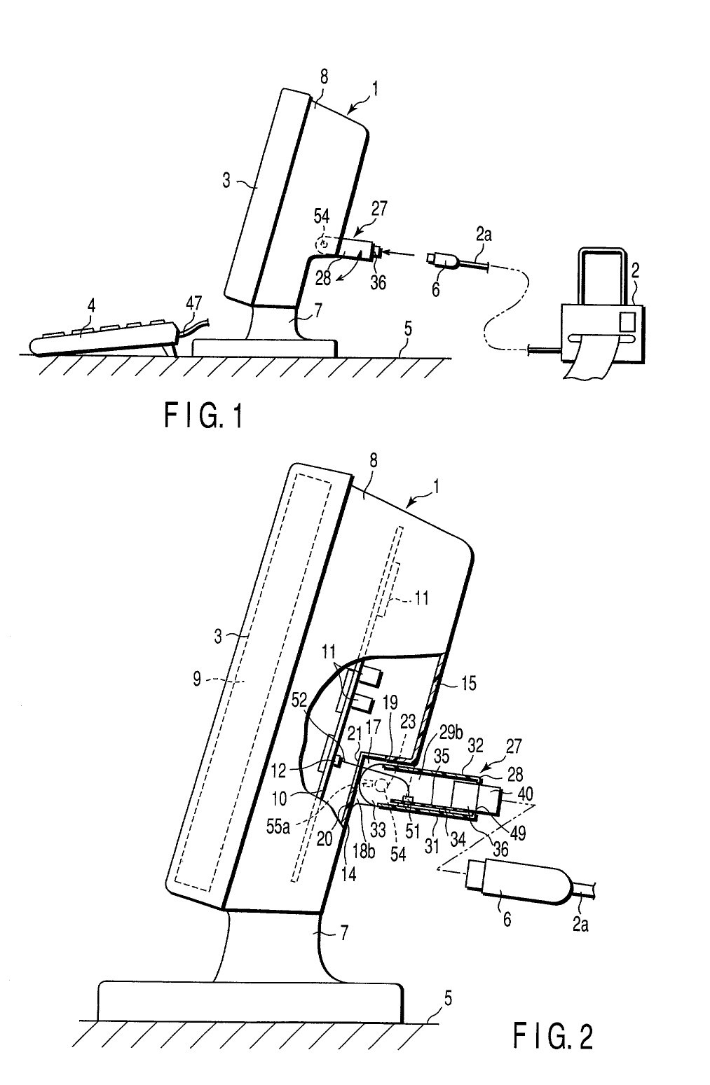

As shown in FIG. 2, the main body 3 comprises a housing 8 and a foot 7 supporting the housing 8. The housing 8 is shaped like a flat box and is vertically placed on the installation surface 5. The housing 8 contains a flat liquid crystal display module 9 and a circuit board 10.

The liquid crystal display module 9 has a display screen (not shown) exposed in front of the housing 8. The circuit board 10 is vertically mounted at the rear of the liquid crystal display module 9. On this circuit board 10, there are mounted a plurality of circuit parts 11 such as semiconductor packages and a first intermediate connector 12. The first intermediate connector 12 is located at the rear of the circuit board 11 opposite the liquid crystal display module 9.

The housing 8 has a rear wall 14 as an external wall. The rear wall 14 vertically extends at the rear of the circuit board 10. A swelling section 15 is formed in the upper half of the rear wall 14 and extends toward the rear of the housing 8.

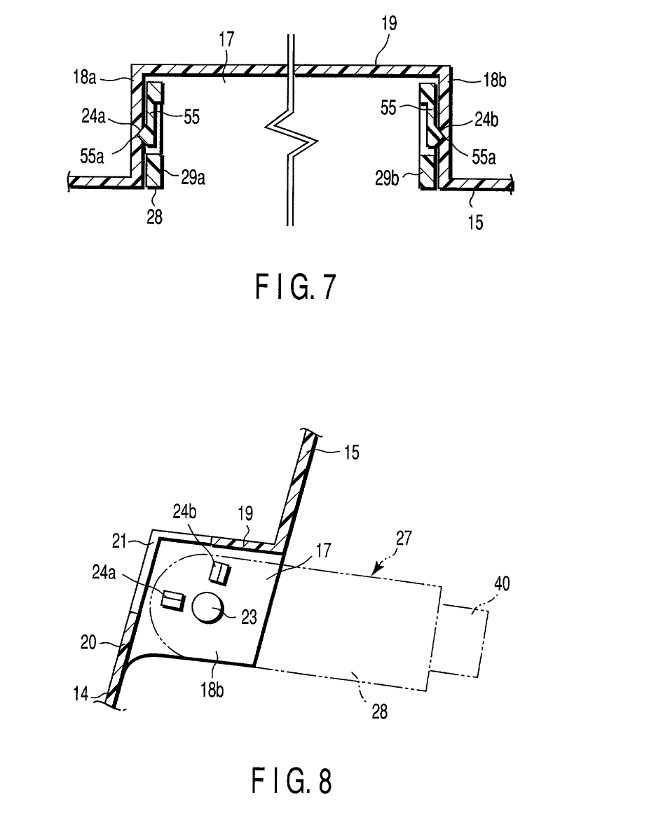

The swelling section 15 has a connector support 17. The connector support 17 is positioned at the bottom of the swelling section 15 and is formed like a recess so as to be opened to the rear and to the bottom of the swelling section 15. As shown in FIGS. 7 and 8 in detail, the connector support 17 is formed by left and right side walls 18a and 18b, an upper wall 19 and a terminal wall 20. The side walls 18a and 18b are parallel arranged apart from each other along the width direction of the housing 8. The upper wall 19 straddles between top ends of the side walls 18a and 18b and is positioned at the bottom of the swelling section 15. The terminal wall 20 straddles between front ends of the side walls 18a and 18b and extends downward from the front end of the upper wall 19. A cable path 21 is formed at a corner restricted by the upper wall 19 and the terminal wall 20. The cable path 21 leads to the inside of the housing 8.

FIG. 8 representatively shows one of the side walls 18a and 18b of the connector support 17. Each side wall has a circular bearing hole 23 and first and second latch recesses 24a and 24b. The bearing hole 23 is positioned along the same axis extending along the width direction of the housing 8. In FIG. 8, the first latch recess 24a is located to the front of the bearing hole 23. The second latch recess 24b is located above the bearing hole 23. Accordingly, the first and second latch recesses 24a and 24b are arranged on a concentric circle around the bearing hole 23 so that these recesses form an almost 90-degree angle measured at the center of the bearing hole 23.

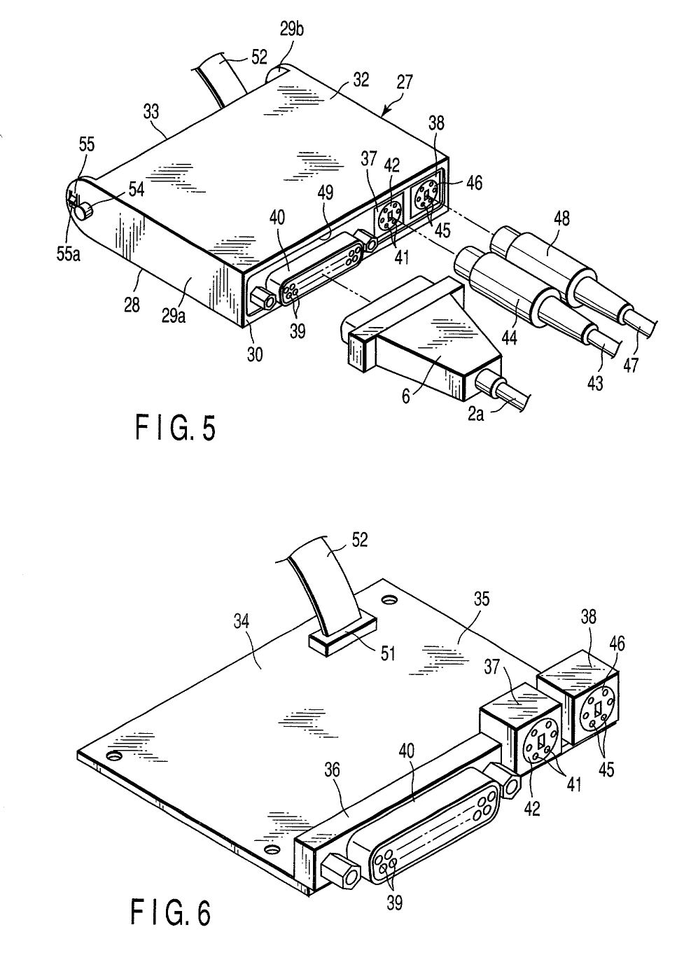

The connector support 17 of the main body 3 supports a connector unit 27 as shown in FIG. 5. The connector unit 27 has a connector housing 28. The connector housing 28 is shaped like a flat box comprising left and right side walls 29a and 29b, a terminal wall 30, a bottom wall 31, and an upper wall 32. The terminal wall 30 is positioned to one end of the connector housing 28. The connector housing 28 has an opening 33 on the other end opposite the terminal wall 30. The opening 33 is opposite the terminal wall 30.

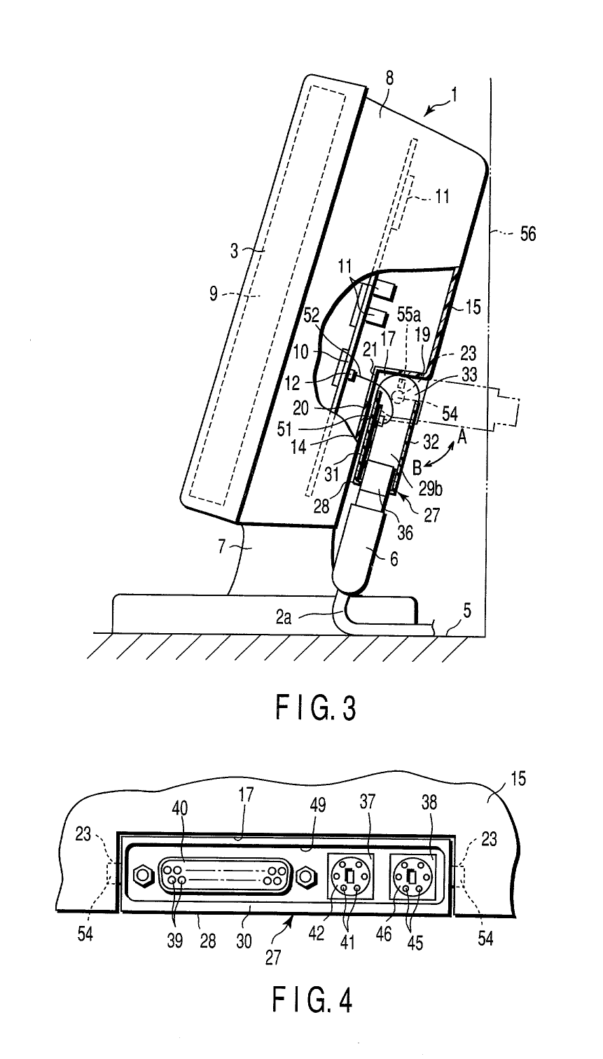

As shown in FIGS. 2 and 3, the connector housing 28 contains a connector board 34. The connector board 34 is screwed to the bottom wall 31 of the connector housing 28 and is arranged parallel to the bottom wall 31. The connector board 34 has a mounting surface 35 facing the upper wall 32. As shown in FIGS. 4 to 6, there are mounted, say, a PRT connector 36 and a pair of PS/2 connectors 37 and 38 on the mounting surface 35 of the connector board 34. These connectors 36 to 38 are arranged along one end of the connector 34 in a line.

The PRT connector 36 corresponds to the cable connector 6 for the printer cable 2a. The PRT connector 36 has a connection section 40 with many pin holes 39 into which pin terminals of the cable connector 6 are inserted detachably.

One PS/2 connector 37 is used for connecting a mouse (not shown). The PS/2 connector 37 has a connection section 42 with a plurality of pin holes 41. A mouse cable 43 extending from the mouse is provided with a cable connector 44 at its end. Pin terminals (not shown) of the cable connector 44 are detachably inserted into the pin holes 41 of the PS/2 connector 37.

The other PS/2 connector 38 is used for connecting the keyboard 4. The PS/2 connector 38 has a connection section 46 with a plurality of pin holes 45. A key board cable 47 extending from the keyboard 4 is provided with a cable connector 48 at its end. Pin terminals (not shown) of the cable connector 48 are detachably inserted into the pin holes 45 of the PS/2 connector 38.

The connection sections 40, 42, and 46 for these connectors 36 to 38 are exposed outside the connector unit 27 through a through-hole 49 in the terminal wall 30.

As shown in FIG. 6, a second intermediate connector 51 is mounted on the mounting surface 35 of the connector board 34. The second intermediate connector 51 is electrically connected to the connectors 36 to 38 via a wiring pattern (not shown) on the connector board 34. A flexible intermediate cable 52 is detachably connected to the second intermediate connector 51. The intermediate cable 52 is extended toward the outside of the connector unit 27 through the opening 33 of the connector housing 28.

The other end of the connector housing 28 is inserted into the connector support 17 of the main body 3. Ends of the side walls 29a and 29b of the connector housing 28 face side walls 18a and 18b of the connector support 17, respectively. The connector housing 28 has a cylindrical shaft portion 54 at each end of the side walls 29a and 29b. The shaft portion 54 rotatively fits into the bearing hole 23 in each of the side walls 18a and 18b in the direction of shaft revolution. Accordingly, the connector unit 27 is supported by the connector support 17 and can rotate between first and second positions around the shaft 54.

FIG. 2 shows that the connector unit 27 is rotated to the first position. With this state, the connector housing 28 is positioned horizontally so that it protrudes from the rear wall 14 of the housing 8 toward the rear. Consequently, the connection sections 40, 42, and 46 of the connectors 36 to 38 are oriented to the rear of the rear wall 14. FIG. 3 shows that the connector unit 27 is rotated to the second position. With this state, the connector housing 28 stands along the rear wall 14 of the housing 8. Consequently, the connection sections 40, 42, and 46 of the connectors 36 to 38 are oriented downward and are directed to the installation surface 5.

As shown in FIGS. 2 and 3, the intermediate cable 52 comes out of the opening 33 of the connector housing 28 and is led into the housing 8 through the cable path 21 of the connector support 17. The tip of the intermediate cable 52 is connected to the first intermediate connector 12 of the circuit board 10. Consequently, three connectors 36 to 38 on the connector board 34 are electrically connected to the circuit board 10 via the intermediate cable 52.

As shown in FIGS. 5 and 7, the side walls 29a and 29b of the connector housing 28 each have a latching strip 55 adjacent to the shaft portion 54. The latching strip 55 includes a projection 55a. The projection 55a protrudes from the tip of the latching strip 55 to the sides of the side walls 29a and 29b. The tip of the latching strip 55 including the projection 55a is cut off from each of the side walls 29a and 29b and is elastically movable toward the inside of the connector housing 28.

When the connector unit 27 is rotated to the first position, the projection 55a of the latching strip 55 elastically engages with the first latch recess 24a of the connector support 17. When the connector unit 27 is rotated to the second position, the projection 55a elastically engages with the second latch recess 24b. In this way, the connector housing 28 is locked to the first or second position. Accordingly, this embodiment uses the projection 55a, the first and second latch recesses 24a and 24b as means for locking the connector unit 27 to the first or second position.

As indicated with arrow A in FIG. 3 in this configuration, rotating the connector unit 27 counterclockwise moves the connector unit 27 to the first position. Further, the projection 55a of the connector housing 28 engages with the first latch recess 24a of the connector support 17, locking the connector unit 27 to the first position.

The connector unit 27 is locked to the first position as shown in FIG. 2. In this state, the connector housing 28 is horizontally positioned so that it protrudes toward the rear of the connector support 17. Consequently, the connection sections 40, 42, and 46 of the connectors 36 to 38 are oriented to the rear of the rear wall 14 on the housing 8. This makes it easy to visually check positions and shapes of the connection section 40, 42, and 46.

As a result, it is possible to stably and promptly connect, say, the cable connector 6 of the printer cable 2a to the connection section 40 of the PRT connector 36, improving workability of connecting the cable connector 6.

After the cable connector 6 is connected to the PRT connector 36, the connector unit 27 is rotated clockwise as indicated with arrow B in FIG. 3. The connector unit 27 moves to the second position from the first position. Due to this movement, the projection 55a of the latching strip 55 is placed onto an edge of the latch recess 24a. The latching strip 55 is pressed against the side walls 18a and 18b of the connector support 17 and is elastically deformed so as to enter the connector housing 28 inward. Accordingly, the projection 55a of the latching strip 55 is released from the first latch recess 24a and does not hinder revolution of the connector unit 27.

When the connector unit 27 reaches the second position, the projection 55a of the latching strip 55 faces the second latch recess 24b. Consequently, the latching strip 55 is restored to the original shape. The projection 55a elastically engages with the second latch recess 24b. Thus, the connector unit 27 is locked to the second position.

The connector unit is locked to the second position as shown in FIG. 3. With this state, the connector housing 28 stands, vertically extending toward the lower end of the connector support 17. The connection sections 40, 42, and 46 of the connectors 36 to 38 are directed downward. This position leads the cable connector 6 of the printer cable 2a connected to the PRT connector 36 toward the bottom of the connector support 17.

Accordingly, it is unnecessary to reserve a space for storing the cable connector 6 or manipulating the printer cable 2a at the rear of the housing 8 on the main body 3. If a wall surface 56 stands just after the installation surface 5, the main body 3 can be installed very close to the wall surface 56 as indicated with a chain double-dashed line in FIG. 3. This feature preserves the space-saving benefit, an advantage of the all-in-one desktop LCD computer 1, and provides a sufficient space for placing the keyboard 4 or documents between a user and the main body 3.

According to the above-mentioned configuration, three connectors 36 to 38 are mounted on the common connector board 34 and is stored in the connector housing 28. It is possible to change the direction of these connectors 36 to 38 at a time, improving workability for connecting three cable connectors 6, 44, and 48 on the connector unit 27.

Moreover, three connectors 36 to 38 are covered with the connector housing 28 except the connection sections 40, 42, and 46. It is possible to tidy up installation portions of these connectors 36 to 38, improving the appearance when the main body 3 is viewed from the rear.

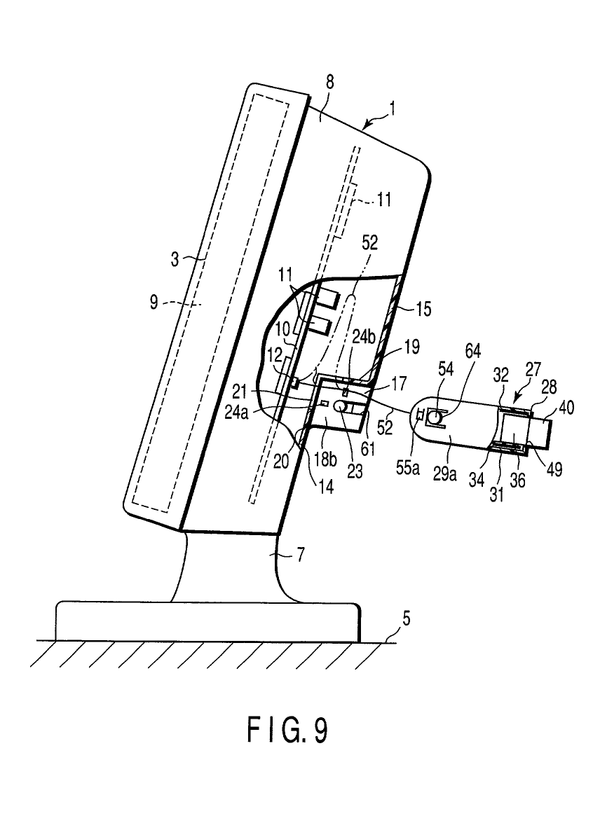

The present invention is not limited to the above-mentioned first embodiment. FIGS. 9 to 13 show the second embodiment of the present invention.

The second embodiment differs from the first embodiment in that the connector unit 27 is removable from the connector support 17 of the housing 8. The other basic configurations for the desktop computer 1 and the connector unit 27 are same as those for the first embodiment. Therefore, the same constituent elements in the second embodiment as those in the first embodiment are depicted by the same reference numerals and the description thereof is omitted.

As shown in FIGS. 9 and 13, the connector support 17 has a guide groove 61 in each of the side walls 18a and 18b. The guide groove 61 guides the shaft portion 54 of the connector housing 28 into the bearing hole 23. The guide groove 61 is wide enough to let the shaft portion 54 slide contactually and is arranged almost horizontally along the depth direction of the main body 3. The guide groove 61 comprises one end leading to the bearing hole 23 and the other end leading to a rear opening of the connector support 17.

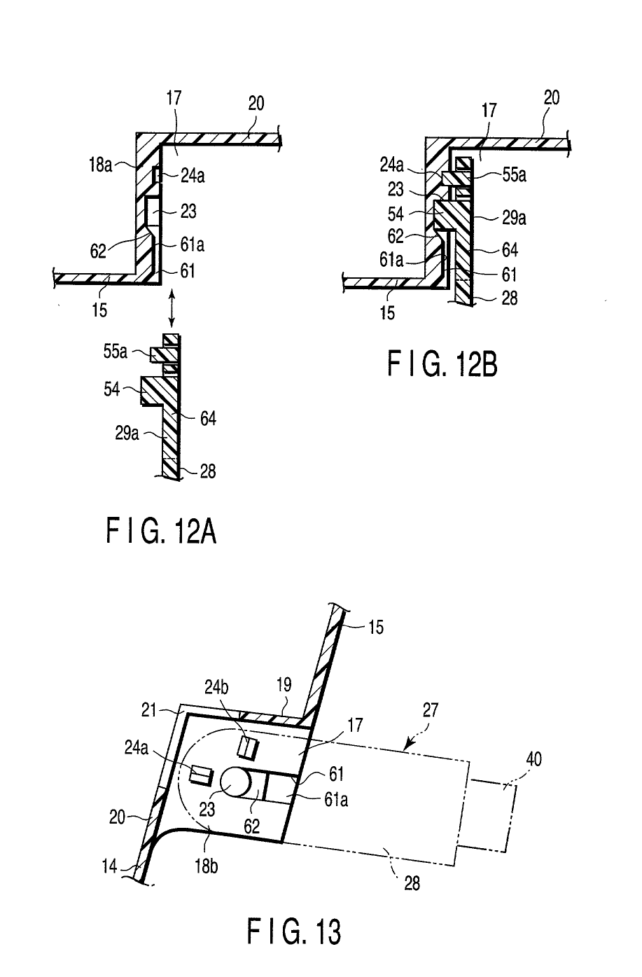

As best illustrated in FIGS. 12A and 12B, a depth of the guide groove 61 is smaller than that of the bearing hole 23. The guide groove 61 has a guide surface 62 on its bottom 61a. The guide surface 62 is located at one end of the guide groove 61 and slants toward the bottom of the bearing hole 23 as nearing this hole. Accordingly, the depth of the guide groove 61 continuously increases as nearing the bearing hole 23.

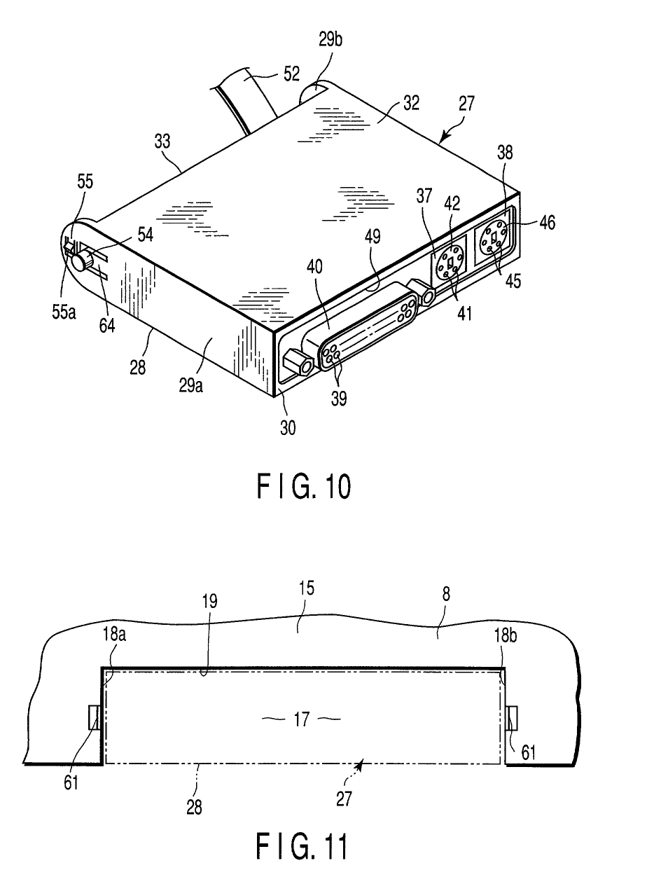

As shown in FIG. 10, a support strip 64 is provided to the side walls 29a and 29b of the connector housing 28. Except one end, the support strip 64 is cut off from each of the side walls 29a and 29b and is elastically movable toward the inside of the connector housing 28. The shaft portion 54 of the connector housing 28 is formed integrally with the other end of the support strip 64. Like the projection 55a of the latching strip 55 as mentioned above, the shaft portion 54 is movable toward the inside of the connector housing 28.

The intermediate cable 52 connects between the connector board 34 and the circuit board 10. When the connector unit 27 is mounted on the connector support 17, the intermediate cable 52 is much longer than the distance between the circuit board 10 and the connector board 34. When the connector unit 27 is mounted on the connector support 17, the intermediate cable 52 is largely stored in the swelling section 15 of the housing 8 as indicated with a chain double-dashed line in FIG. 9.

When the connector unit 27 is rotated to the first position in this configuration, the connector unit can be pulled out of the connector support 17. At this time, the projection 55a of the latching strip 55 shifts onto the edge of the first latch recess 24a and elastically moves in the direction departing from the first latch recess 24a.

Further, the shaft portion 54 shifts onto the guide surface 62 of the guide groove 61 and is pressed against the guide surface 62. The shaft portion 54 then moves into the connector housing 28 together with the support strip 64 and is disengaged from the bearing hole 23. The shaft portion 54 and the projection 55a of the latching strip 55 are pulled outside the connector support 17 along the guide groove 61.

As shown in FIG. 9, the connector unit 27 can be removed from the main body 3 as far as the intermediate cable 52 reaches. This increases the freedom of positioning among three connection sections 40, 42, and 46 of the connector unit 27 and the cable connectors 6, 44, and 48. It is possible to more easily connect the connector unit 27 to the cable connectors 6, 44, and 48.

When the connector unit 27 connects with the cable connectors 6, 44, and 48, the shaft portion 54 of the connector housing 28 is placed at the rear opening of the guide groove 61. The shaft portion 54 is inserted into the connector support 17 along the guide groove 61. When the shaft portion 54 passes the guide surface 62 to reach the bearing hole 23, the shaft portion 54 is released from the pressure by the guide surface 62. The shaft 54 then elastically fits into the bearing hole 23. Thus, the connector unit 27 is rotatively coupled to the connector support 17. Accordingly, the connector unit 27 can be rotated from the first position to the second position.

When the connector unit 27 is rotated to the second position, the connector housing 28 stands, vertically extending toward the lower end of the connector support 17 like the first embodiment. This position downward orients the connection sections 40, 42, and 46 of the connectors 36 to 38. The cable connectors 6, 44, and 48 protrude from the connector support 17 downward. Accordingly, it is unnecessary to reserve a space for storing the cable connectors 6, 44, and 48 or manipulating the cables 2a, 43, and 47 at the rear of the housing 8 on the main body 3. The main body 3 can be installed close to the wall surface 56.

Additionally, the intermediate cable 52 can be removed from the connector unit 27 in the second embodiment. Further, the connector 27 and the connector support 17 of the housing 8 may be separated from each other.

According to the present invention, the connector unit 27 can be used as a USB hub. For this purpose, the second intermediate connector 51 is replaced by a first USB connector. The connectors 36 to 38 are replaced by second USB connectors. In this case, the second intermediate connector 51 is assumed to be the upstream side near the main body 3. The connectors 36 to 38 are assumed to be the downstream side near peripheral devices. Accordingly, the main body 3 can connect with many peripheral equipments in a tree fashion via the connector unit 27, maximizing features of the desktop computer 1.

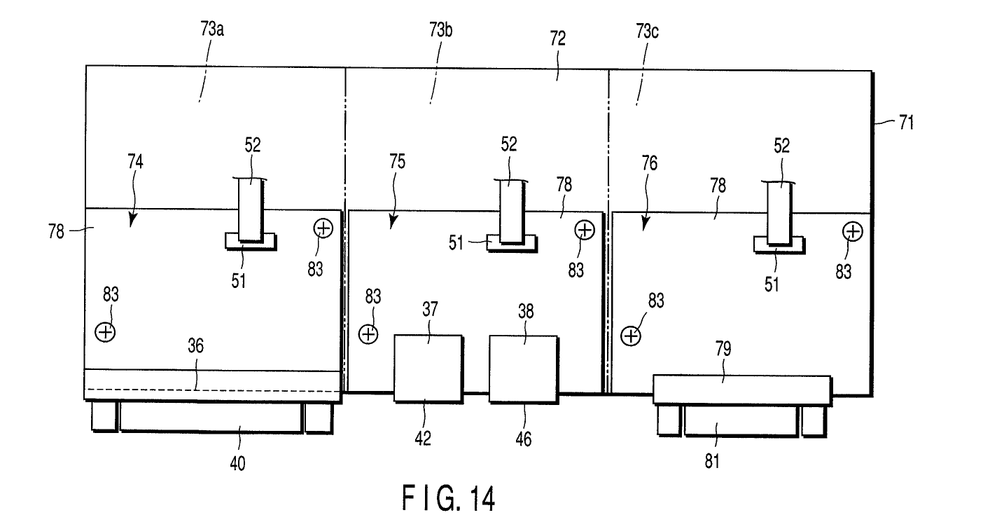

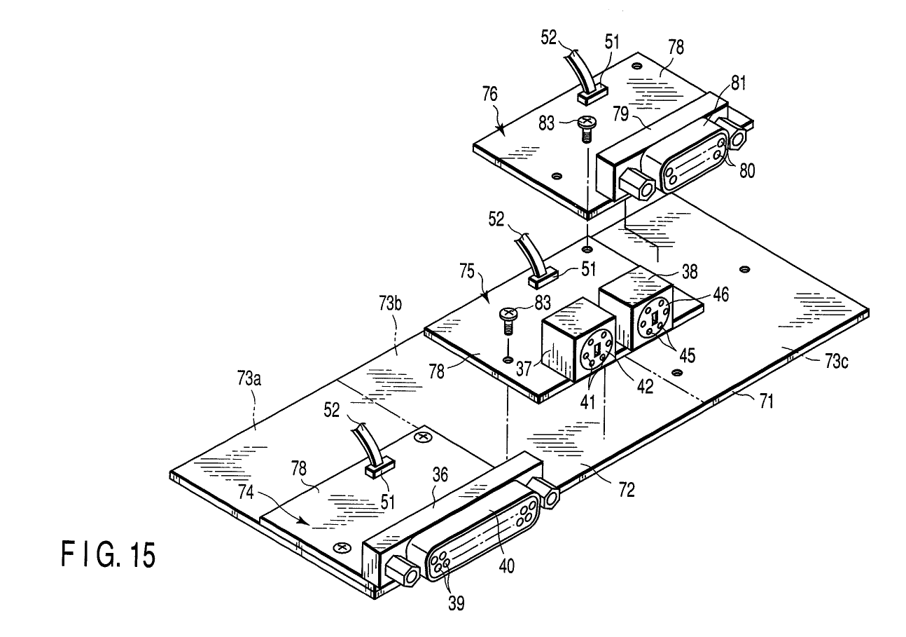

FIGS. 14 and 15 disclose the third embodiment of the present invention.

The third embodiment is chiefly characterized in that an internal structure of the connector unit 27 differs from the first embodiment. The basic configurations for the desktop computer 1 including the structure for mounting the connector unit 27 are same as those for the first embodiment. Therefore, the same constituent elements in the third embodiment as those in the first embodiment are depicted by the same reference numerals and the description thereof is omitted.

In FIGS. 14 and 15, a base 71 is a flat, rectangular plate. The base 71 is contained in the connector housing 28 and is detachably supported on the bottom wall 31 of the connector housing 28. The base 71 has a flat connector installation surface 72. The connector installation surface 72 is divided into three mounting regions 73a, 73b, and 73c. The mounting regions 73a, 73b, and 73c are equally sized and are arranged in a line along a longer direction of the base 71.

The mounting regions 73a to 73c are provided with first to third connector modules 74 to 76. The first to third connector modules 74 to 76 each have connector boards 78. These connector boards 78 are equally sized.

On the connector board 78 for the first circuit module 74, there are mounted the PRT connector 36 and the second intermediate connector 51. The PRT connector 36 is located at one end of the connector board 78 and is electrically connected to the second intermediate connector 51 via a wiring pattern (not shown) on the connector board 78.

On the connector board 78 for the second circuit module 75, there are mounted a pair of PS/2 connectors 37 and 38 and the second intermediate connector 51. The PS/2 connectors 37 and 38 are electrically connected to the second intermediate connector 51 via a wiring pattern (not shown) on the connector board 78.

On the connector board 78 for the third circuit module 76, there are mounted an RGB connector 79 and the second intermediate connector 51. The RGB connector 79 is electrically connected to the second intermediate connector 51 via a wiring pattern (not shown) on the connector board 78. The RGB connector 79 is used for connecting an external CRT display (not shown) and has a connector section 81 with a plurality of pin holes 80.

The first to third circuit modules 74 to 76 are selectively and detachably supported on any of mounting regions 73a to 73c on the connector installation surface 72 by means of screws 83. The connectors 36 to 38 and 79 of the circuit modules 74 to 76 are arranged in a line along a longer direction of the base 71. The connection sections 40, 42, 46, and 81 of the connectors 36 to 38 and 79 are exposed outside the connector unit 27 from the through-hole 49 in the connector housing 28.

According to this configuration, the connector unit 27 is mounted with the first to third connector modules 74 to 76 and is rotatively supported by the connector support 17 of the main body 3. Like the first embodiment, it is possible to easily connect the cable connectors 6, 44, and 48 to the connection sections 40, 42, 46, and 81 by rotating the connector unit 27 to the first position. This position rearward orients the connection sections 40, 42, 46, and 81 of the connector modules 74 to 76. Rotating the connector unit 27 to the second position directs the connection sections 40, 42, 46, and 81 downward, preventing the cable connectors 6, 44, and 48 from protruding from the main body 3 rearward. This feature preserves the space-saving benefit.

Further, the first to third connector modules 74 to 76 are selectively detachable from the base 71. In addition to the connector modules 74 to 76, a user can freely choose from many connector modules with different types of connectors as needed and install the selected modules on the base 71. This provides an advantage of increasing the freedom of connecting peripheral devices to the main body 3 and improving operability.

An external wall of the main body according to the present invention is not limited to the rear wall of the main body, but includes a side wall to the side of the main body. Accordingly, it may be preferable to rotatively install the connector unit not only on the rear wall, but also on the side wall of the main body.

In the above-mentioned embodiments, the connector unit is rotated around the horizontal axis extending along the width direction of the main body. The rotation direction of the connector unit is not limited thereto. Specifically, it may be preferable to rotate the connector unit around the vertical axis extending along the height direction of the main body. According to this configuration, the connector unit can rotatively move between the first position protruding the connector unit from the external wall and the second position letting the connector unit stand along the external wall. In this second position, the connector unit is stationed so that the connector section is directed sideways along the external wall.

The electronic apparatus according to the present invention is not limited to the all-in-one desktop LCD computer, but is also applicable to a server or a liquid crystal television set having a plurality of connectors on the rear.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. An electronic apparatus comprising:
a main body having an external wall; and
at least one connector supported by said main body,
wherein said connector has a connection section to which a cable connector attached to a cable is detachably connected and is movable between a first position directing said connection section sideways against said external wall and a second position directing said connection section downward against said external wall.

2. The electronic apparatus according to claim 1, further comprising:
a connector housing storing said connector,
wherein said connector housing has one end for outward exposing said connection section of said connector and the other end rotatively supported by said main body.

3. The electronic apparatus according to claim 2, wherein
said main body and said connector housing include means for locking said connector to said first position or said second position.

4. The electronic apparatus according to claim 1, wherein
said main body comprises a box-shaped housing, a foot for supporting this housing, and a liquid crystal display module enclosed in said housing.

5. The electronic apparatus according to claim 1,
wherein said connector is detachably supported by said main body, and, when mounted on said main body, is movable between a first position directing said connection section sideways against said external wall and a second position directing said connection section downward against said external wall.

6. An electronic apparatus comprising:
a main body having an external wall; and
a connector unit supported by said main body, wherein said connector unit comprises a connector housing, a connector board contained in said connector housing, and at least one connector mounted on said connector board and having a connection section detachably connecting a cable connector attached to a cable; and
said connector unit is movable between a first position directing said connection section sideways against said external wall and a second position directing said connection section downward against said external wall.

7. The electronic apparatus according to claim 6, wherein
said main body contains a circuit board; and
said circuit board is electrically connected to said connector board via a flexible intermediate cable.

8. The electronic apparatus according to claim 7, wherein
said connector unit is detachably supported by said main body and, when mounted on said main body, is movable between said first and second positions; and
said intermediate cable is longer than a distance between said circuit board and said connector board when said connector unit is mounted on said main body.

9. The electronic apparatus according to claim 6, wherein
said connector housing comprises a pair of side walls and a shaft which is provided at each end of said side walls and is elastically movable toward the inside of said connector housing;
said external wall has a recess where an end of said connector housing is inserted detachably; and
said recess comprises a bearing hole for rotatively fitting said shaft in the direction of shaft revolution and means for guiding said shaft into said bearing hole and releasing said shaft from said bearing hole.

10. An electronic apparatus comprising:
a main body having an external wall; and
a connector unit supported by said main body, wherein
said connector unit includes a plurality of connector modules having connection sections detachably connecting cable connectors attached to cables and a base selectively and detachably supporting said connector modules; and
said connector unit is movable between a first position directing said connection section sideways against said external wall and a second position directing said connection section downward against said external wall.

11. The electronic apparatus according to claim 10, wherein
said main body contains a circuit board;
said connector module comprises a connector board selectively and detachably supported by said base and at least one connector mounted on said connector board and having said connection section; and
said connector board for said connector module is electrically connected to said connector board via an intermediate cable.

12. A connector device used for an electronic apparatus having an external wall, comprising:
a connector housing supported by said electronic apparatus; and
at least one connector enclosed in said connector housing and having a connection section detachably connecting a cable connector attached to a cable,
wherein said connector housing is movable between a first position directing said connection section sideways against said external wall and a second position directing said connection section downward against said external wall.

13. The connector device according to claim 12, wherein
said connector housing is removable from said electronic apparatus and, when mounted on said electronic apparatus, is rotatively movable between said first position and said second position.

14. The connector device according to claim 12, wherein
said connector housing has one end for outward exposing said connection section and the other end rotatively supported by said electronic apparatus.

15. The connector device according to claim 12, wherein
said connector housing is selectively locked to said first position or said second position.
